(19) United States
(12) Patent Application Publication
(10) Pub. No.: US 2026/0211019 A1
(43) Pub. Date: Jul. 23, 2026

(54) MEASUREMENT APPLICATION DEVICE, MEASUREMENT APPLICATION SYSTEM, AND METHOD

(71) Applicant: Rohde & Schwarz GmbH & Co. KG, München (DE)

(72) Inventor: Kai-Uwe SCHMIDT, München (DE)

(21) Appl. No.: 18/771,244

(22) Filed: Jul. 12, 2024

(30) Foreign Application Priority Data
Jul. 14, 2023 (EP) 23185703.8
Feb. 19, 2024 (EP) 24158492.9
Feb. 20, 2024 (EP) 24158746.8

(51) Int. Cl. G01R 27/28

(52) U.S. Cl. CPC G01R 27/28

(57) ABSTRACT

The present disclosure provides a measurement application device that includes a signal interface that acquires or outputs a measurement application signal, a signal processor that processes a measurement application signal acquired by the signal interface or processes a measurement application signal to be output by the signal interface and provide the processed measurement application signal to the signal interface, and a user interface, where command memory includes firmware that cause the signal processor to perform the signal processing. The measurement application device further includes a signal processing command interface that is coupled to the command memory and that is configured to receive computer-readable extension commands, where the firmware can causes the signal processor to store the received computer-readable extension commands in the command memory, or to execute the received computer-readable extension commands according to respective user input received via the user interface.

### TECHNICAL FIELD

The disclosure relates to a measurement application device, a measurement application system, and a respective method.

### BACKGROUND

Although applicable to any type of measurement application device, the present disclosure will mainly be described in conjunction with laboratory equipment, like oscilloscopes and vector network analyzers, VNAs.

Modern test and measurement instruments, e.g., Oscilloscopes and Vector Network Analyzers, offer sophisticated workflows with specialized measurements to assist the users in measuring complex devices under test, also called DUT. Typically, these workflows ask the user for key parameters like the class of DUT (e.g. amplifier) or key parameters they want to measure (e.g. NF within a certain frequency range). Generally, such test and measurement instruments are not easily extensible.

Accordingly, there is a need for improving extensibility of test and measurement devices.

### SUMMARY

The above stated problem is solved by the features of the independent claims. It is understood, that independent claims of a claim category may be formed in analogy to the dependent claims of another claim category.

Accordingly, it is provided:

A measurement application device for at least one of acquiring from and generating for an electric device under test at least one of electric, magnetic and electromagnetic signals, the measurement application device comprising a signal interface configured to at least one of acquire and output a measurement application signal, a signal processor coupled to the signal interface, wherein the signal processor is configured at least one of to process a measurement application signal acquired by the signal interface and to process a measurement application signal to be output by the signal interface and provide the processed measurement application signal to the signal interface, and a user interface coupled to the signal processor, wherein the signal processor is coupled to or comprises a non-transitory command memory that comprises a firmware with computer-readable commands that when executed by the signal processor at least cause the signal processor to perform the signal processing, and wherein the measurement application device further comprises a signal processing command interface that is coupled to the command memory and that is configured to receive computer-readable extension commands, wherein firmware further comprises computer-readable commands that when executed by the signal processor, cause the signal processor at least one of to store the received computer-readable extension commands in the command memory, and to execute the received computer-readable extension commands according to respective user input received via the user interface.

Further, it is provided:

A measurement application system comprising an external code generator configured to generate computer-readable extension commands based on a respective user request and to provide the generated computer-readable extension commands to a measurement application device, and a measurement application device that comprises a signal interface configured to at least one of acquire from and output for an electric device under test at least one of electric, magnetic and electromagnetic measurement application signal, a signal processor coupled to the signal interface, wherein the signal processor is configured at least one of to process the measurement application signal acquired by the signal interface, and to process a measurement application signal to be output by the signal interface and provide the processed measurement application signal to the signal interface, a user interface coupled to the signal processor, and a communication interface coupled to the signal processor, wherein the signal processor is coupled to or comprises a non-transitory command memory that comprises a firmware with computer-readable commands that when executed by the signal processor at least cause the signal processor to perform the signal processing, and wherein the signal processor further comprises a signal processing command interface that is coupled to the command memory and that is configured to receive computer-readable extension commands, wherein firmware further comprises computer-readable commands that when executed by the signal processor, cause the signal processor to at least one of store the received computer-readable extension commands in the command memory, and execute the received computer-readable extension commands according to respective user input received via the user interface, wherein the signal processor is further configured to receive a user request for code generation from a user via the user interface, and to provide the user request for code generation to the external code generator via the communication interface or an internal code generator of the measurement application device, and to receive the computer-readable extension commands from the respective code generator via the signal processing command interface.

Further, it is provided:

A method for operating a measurement application system that comprises a measurement application device and an external code generator that is external to the measurement application device, the method comprising receiving a user request for code generation from a user at the measurement application device, providing the user request for code generation to the external code generator or an internal code generator that is provided internal in the measurement application device, generating computer-readable extension commands with the external code generator or the internal code generator, respectively, based on the received user request, and receiving, and at least one of storing and executing the generated computer-readable extension commands in the measurement application device according to respective user input received at the measurement application device.

The present disclosure is based on the finding that measurement workflows and types of measurements are usually hard-coded, e.g., directly into the firmware of the respective measurement application device. When a user requires a new workflow or new types of measurements to be implemented, this is usually achieved by requesting the manufacturer of the measurement application device to implement the required functionality and waiting until a new firmware is released for the respective measurement application device.

The present disclosure, therefore, provides a measurement application device, a respective measurement application system, and a respective method that allow easily extending the functionality of a measurement application device.

To this end, the measurement application device comprises a signal interface that is coupled to a signal processor. The signal processor may process measurement application signals received by the signal interface, or may process, e.g., generate measurement application signals to be output via the signal interface.

The measurement application device further comprises a non-transitory command memory that comprises the firmware of the measurement application device. Usually, the firmware will provide the full functionality of the measurement application device and cause the signal processor or any other processing element in the measurement application device to perform the respective functions. The firmware is provided in a non-transitory command memory and comprises respective computer-readable commands.

Such a firmware may be provided as actual code that is executed by a processor. The firmware may also comprise a configuration written in a respective logic description language, like VHDL or VERILOG, that is loaded into a configurable logic element to implement the respective functions. In embodiments, the firmware may also comprise scripts that are provided in a scripting language, like Python. In embodiments, the firmware may comprise any combination of the above.

The measurement application device further comprises a signal processing command interface that is coupled to the command memory and that is configured to receive computer-readable extension commands. The term “computer-readable extension commands” in this context refers to commands that may be provided to the measurement application device for execution without being part of the firmware of the measurement application device. Such computer-readable extension commands may be provided, e.g., as executable program that may be called or executed by the firmware of the measurement application device. In embodiments, the computer-readable extension commands may also comprise commands in a scripting language that is not compiled but interpreted. A respective interpreter may be provided in the firmware or as application that may be executed by the firmware.

The firmware further comprises computer-readable commands that when executed by the signal processor, cause the signal processor at least one of to store the received computer-readable extension commands in the command memory, and to execute the received computer-readable extension commands according to respective user input received via the user interface.

That means that the received computer-readable extension commands may be stored for later use and execution after a user request, or may immediately be executed.

By providing the measurement application device with the option to receive computer-readable extension commands, the functionality of the measurement application device may easily be extended beyond the functionality provided by the firmware.

A measurement application device according to the present disclosure may comprise any device that may be used in a measurement application to acquire an input signal or to generate an output signal, or to perform additional or supporting functions in a measurement application. In embodiments, a respective measurement application device may be configured for at least one of acquiring from and generating for an electric device under test at least one of electric, magnetic and electromagnetic signals.

A measurement application device may also comprise or be implemented as program application or program applications, also called measurement program application or measurement program applications, that may be executed on a computer device and that may communicate with other measurement application devices in order to perform a measurement task. A measurement application, also called measurement setup, may e.g., comprise at least one or multiple different measurement application devices for performing electric, magnetic, or electromagnetic measurements, especially on single devices under test. Such electric, magnetic, or electromagnetic measurements may e.g., be performed in a measurement laboratory or in a production facility in the respective production line. An exemplary measurement application or measurement setup may serve to qualify the single devices under test i.e., to determine the proper electrical operation of the respective devices under test.

Measurement application devices to this end may comprise at least one signal acquisition section for acquiring electric, magnetic, or electromagnetic signals to be measured from a device under test, or at least one signal generation section for generating electric, magnetic, or electromagnetic signals that may be provided to the device under test. Such a signal acquisition section may comprise, but is not limited to, a front-end for acquiring, filtering, and attenuating or amplifying electrical signals. The signal generation section may comprise, but is not limited to, respective signal generators, amplifiers, and filters. In embodiments, the signal acquisition is performed via the signal acquisition section in a wired or contact-based manner or fashion. To this end, a respective measurement probe may be coupled to the measurement application device via a respective cable. In embodiments, the signal generation and emission is performed via the signal generation section in a wired or contact-based manner or fashion. To this end, a respective signal output probe may be coupled to the measurement application device via a respective cable, or the signal may be output directly via the cable e.g., to a device under test.

Further, when acquiring signals, measurement application devices may comprise a signal processing section that may process the acquired signals. Processing may comprise converting the acquired signals from analog to digital signals, and any other type of digital signal processing, for example, converting signals from the time-domain into the frequency-domain.

The measurement application devices may also comprise a user interface to display the acquired signals to a user and allow a user to control the measurement application devices. Of course, a housing may be provided that comprises the elements of the measurement application device. It is understood, that further elements, like power supply circuitry, and communication interfaces may be provided.

A measurement application device may be a stand-alone device that may be operated without any further element in a measurement application to perform tests on a device under test. Of course, communication capabilities may also be provided for the measurement application device to interact with other measurement application devices.

A measurement application device may comprise, for example, a signal acquisition device e.g., an oscilloscope, especially a digital oscilloscope, a spectrum analyzer, or a vector network analyzer. Such a measurement application device may also comprise a signal generation device e.g., a signal generator, especially an arbitrary signal generator, also called arbitrary waveform generator, or a vector signal generator. Further possible measurement application devices comprise devices like calibration standards, or measurement probe tips.

Of course, at least some of the possible functions, like signal acquisition and signal generation, may be combined in a single measurement application device.

In embodiments, the measurement application device may comprise pure data acquisition devices that are capable of acquiring an input signal and of providing the acquired input signal as digital input signal to a respective data storage or application server. Such pure data acquisition devices not necessarily comprise a user interface or display. Instead, such pure data acquisition devices may be controlled remotely e.g., via a respective data interface, like a network interface or a USB interface. The same applies to pure signal generation devices that may generate an output signal without comprising any user interface or configuration input elements. Instead, such signal generation devices may be operated remotely via a data connection.

Further embodiments of the present disclosure are subject of the further dependent claims and of the following description, referring to the drawings.

In the following, the dependent claims referring directly or indirectly to claim 1 are described in more detail. For the avoidance of doubt, the features of the dependent claims relating to independent claim 1 can be combined in all variations with each other and the disclosure of the description is not limited to the claim dependencies as specified in the claim set. Further, the features of the dependent claims referring to independent claim 1 may be combined with any of the features of the other independent claims or the dependent claims relating to any one of the other independent claims. In a respective method, respective method steps may perform the function of the respective apparatus elements, and in a respective apparatus, respective apparatus elements may perform the respective method steps.

In an embodiment, which can be combined with all other embodiments mentioned above or below, the measurement application device may further comprise a code verification processor that may be coupled to either one or both of the command memory and the signal processing command interface. The code verification processor may be configured to inspect the received computer-readable extension commands for compliance with a predetermined device rule set for the measurement application device. The signal processor may further be configured to reject the received computer-readable extension commands if the code verification processor determines that the received computer-readable extension commands do not comply with the predetermined device rule set.

In embodiments the code verification processor may be included in or may be provided as part of or as additional function of the signal processor or the firmware.

The code verification processor may in embodiments comprise logic that performs a kind of static code analysis. In embodiments, the code verification processor may also comprise a pre-trained artificial intelligence algorithm that is trained to perform the code analysis. The code verification processor verifies that no one of the computer-readable extension commands performs harmful operations with the measurement application device.

The term “harmful” in this context may refer to commands that may physically damage the measurement application device or the respective device under test. The term “harmful” may also refer to commands that try to breach security measures of the measurement application device and try to hack into the measurement application device.

The code verification processor helps to reduce the risk of any externally provided computer-readable extension commands harming the measurement application device or the respective device under test.

In a further embodiment, which can be combined with all other embodiments mentioned above or below, the measurement application device may further comprise a code generator that is coupled to the signal processing command interface and that is configured to generate the computer-readable extension commands based on a respective user request and provide the generated computer-readable extension commands to the signal processing command interface.

The code generator may receive a user request via any type of adequate interface. For example, a keyboard or a microphone may be provided that allow a user to provide the respective user request for generating the computer-readable extension commands.

The code generator may not only generate a single computer-readable extension command, but may create a full program or script comprising a plurality of computer-readable extension commands that provide the requested functionality.

In another embodiment, which can be combined with all other embodiments mentioned above or below, the code generator may comprise a pre-trained artificial intelligence algorithm that may be pre-trained to generate computer-readable extension commands for the measurement application device based on the respective user request, while any other type of code generator is also possible. The capabilities of the code generator may be provided according to the computational capabilities of the measurement application device. This means, that the capabilities of the code generator to locally generate computer-readable extension commands in the measurement application device may be limited. To overcome this limitations, an external code generator may also be provided, as will be explained in more detail below.

A pre-trained artificial intelligence algorithm may comprise, e.g., an algorithm that is based on a large language model. By using a pre-trained artificial intelligence algorithm as code generator, the user is enabled to provide the user request in natural language as if he was speaking to a firmware developer.

Such a natural language communication simplifies the interaction between the user and the measurement application device or the code generator.

A code generator that is based on a pre-trained artificial intelligence algorithm may, e.g., be trained with training data taken, e.g., from manuals, datasheets, and available measurement reports, that comprise descriptions of measurement results, and e.g., images of measured waveforms.

In another further embodiment, which can be combined with all other embodiments mentioned above or below, the code generator may be configured to provide computer-readable extension commands that when executed by the signal processor cause the signal processor to perform calculations based on the measurement application signal, and to control a display of the measurement application device to display the calculation results.

Usually, a user after performing a measurement of a measurement application signal or after generating the measurement application signal needs to perform further analysis of this signal. If the required functionality is not yet provided in the respective measurement application device, the code generator may provide this functionality.

By enabling the code generator to provide computer-readable extension commands for performing calculations based on the measurement application signal and displaying the calculation results, such a possibility is provided to the users. This allows any user, even without having special technical knowledge on how to program the measurement application device, to perform the required signal analysis.

In another embodiment, which can be combined with all other embodiments mentioned above or below, the measurement application device further comprises a complexity estimator configured to determine the complexity of the respective user request, and provide the respective user request to the code generator, if the determined complexity is below a predetermined threshold.

As indicated above, a locally executed code generator may be adapted to the processing and memory resources that are locally available in the respective measurement application device.

Consequently, such a code generator may not comprise the capacity to answer all possible user requests, and may be limited to answer only simple user requests.

In order to allow a user to use complex user requests, the measurement application device may be provided with the complexity estimator.

The complexity estimator may analyze the received user requests, and may determine or estimate the complexity of the user requests. If the determined or estimated complexity is higher than a predetermined threshold, the respective user request may be provided to an external, more powerful pre-trained artificial-intelligence algorithm, as will be explained below. The external pre-trained artificial-intelligence algorithm may e.g., be provided as network attached server or cloud server.

The predetermined threshold may, of course, be adapted to the capabilities of a locally executed code generator. An exemplary complexity measure may e.g., comprise the number of letters, or the number of words, or the number of sentences, or a combination of any of these.

In a further embodiment, which can be combined with all other embodiments mentioned above or below, the measurement application device may further comprise a communication interface, wherein the complexity estimator is further configured to provide the user request to an external code generator that is external to the measurement application device via the communication interface if the determined complexity is above the predetermined threshold.

The external code generator may communicatively be coupled to the measurement application device, e.g., in a respective measurement application system. The explanations regarding the implementation of the local or internal code generator apply to the external code generator mutatis mutandis. However, the resources available to the external code generator may be huge compared to the local resources available to the internal code generator of the measurement application device.

In another embodiment, which can be combined with all other embodiments mentioned above or below, the complexity estimator may be further configured to only provide the user request to an external code generator after receiving a respective user consent.

Data regarding a measurement setup, or a measurement application may be confidential. Therefore, the complexity estimator may ask a user for consent or permission prior to providing or transmitting a user request to an external code generator.

If the user declines, the complexity estimator may inform the user that the user requests may eventually not be answered correctly with the locally executed code generator, and provide the text-based user requests to the local code generator.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows a block diagram of an embodiment of a measurement application device according to the present disclosure;

FIG. 2 shows a block diagram of another embodiment of a measurement application device according to the present disclosure ;

FIG. 3 shows a block diagram of a further embodiment of a measurement application device according to the present disclosure;

FIG. 4 shows a block diagram of an embodiment of a measurement application system according to the present disclosure;

FIG. 5 shows a flow diagram of an embodiment of a method according to the present disclosure;

FIG. 6 shows a block diagram of another embodiment of a measurement application device according to the present disclosure; and

FIG. 7 shows a block diagram of a further embodiment of a measurement application device according to the present disclosure.

In the figures like reference signs denote like elements unless stated otherwise.

### DETAILED DESCRIPTION OF THE DRAWINGS

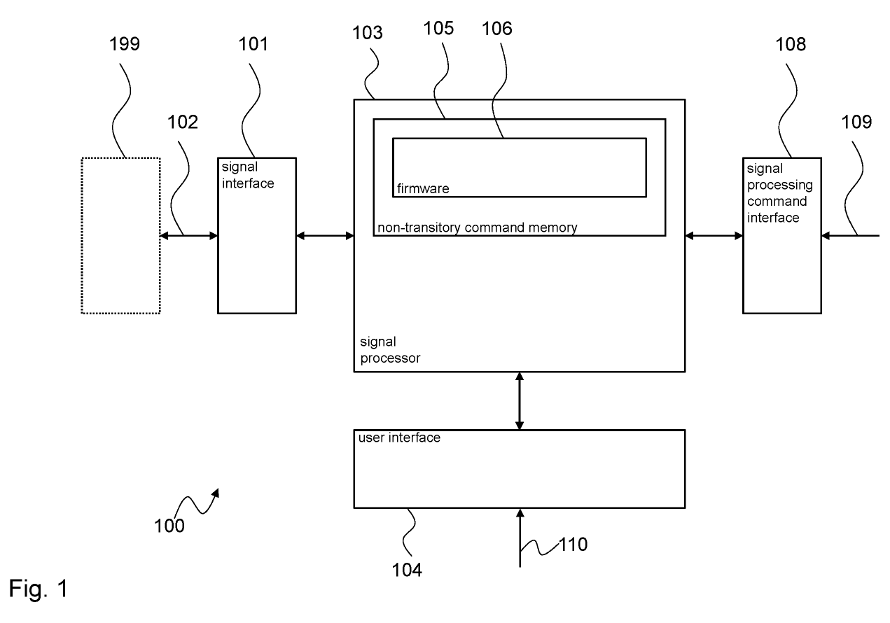

FIG. 1 shows a block diagram of a measurement application device 100. The measurement application device 100 serves for acquiring from and/or generating for an electric device under test, also called DUT 199, at least one of electric, magnetic and electromagnetic signals. The measurement application device 100 comprises a signal interface 101 that acquires and/or outputs a measurement application signal 102. The signal interface 101 is coupled to a signal processor 103. The signal processor 103 is coupled to a user interface 104, and to a signal processing command interface 108. The explanations provided herein for any other embodiment of the measurement application device apply mutatis mutandis to the measurement application device 100.

The signal processor 103 processes the measurement application signal 102 when acquired by the signal interface 101 and/or processes, e.g., generate, the measurement application signal 102 to be output by the signal interface 101. The signal processor 103 comprises a non-transitory command memory 105 that comprises a firmware 106 with computer-readable commands that when executed by the signal processor 103 at least cause the signal processor to perform this signal processing of the measurement application signal 102. In embodiments, the non-transitory command memory 105 with the firmware 106 may be provided externally to the signal processor 103. In further embodiments, the firmware 106 may be provided in an additional memory that is external to the signal processor 103.

The signal processing command interface 108 is coupled to the command memory 105 and may receive computer-readable extension commands 109. The firmware 106 further comprises computer-readable commands that when executed by the signal processor 103, cause the signal processor 103 to store the received computer-readable extension commands 109 in the non-transitory command memory 105, and/or to execute the received computer-readable extension commands 109 according to respective user input received 110 via the user interface 104.

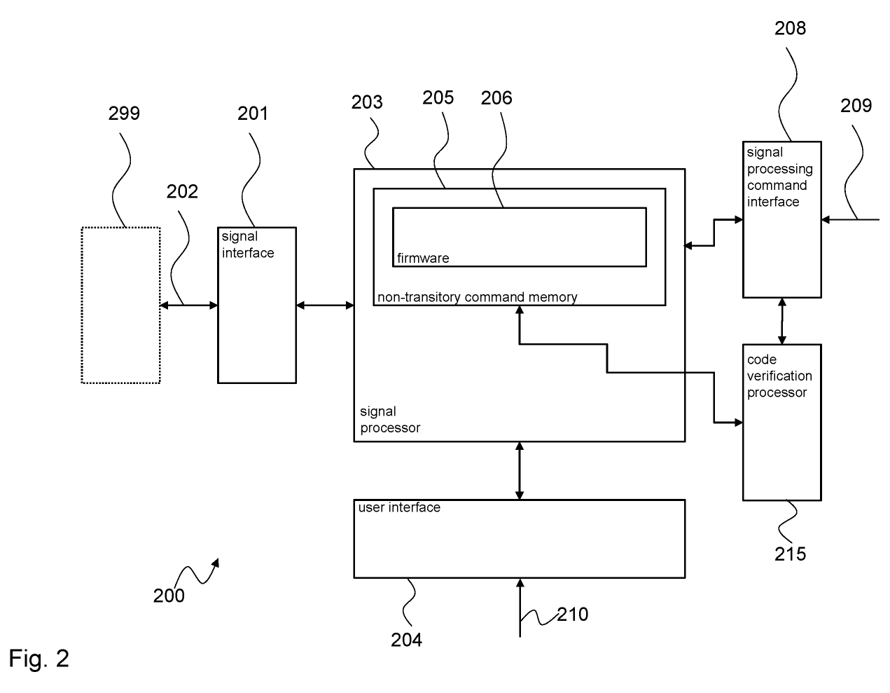

FIG. 2 shows a block diagram of another measurement application device 200. The measurement application device 200 is based on the measurement application device 100. Therefore, the measurement application device 200 comprises a signal interface 201 that acquires and/or outputs a measurement application signal 202. The signal interface 201 is coupled to a signal processor 203. The signal processor 203 is coupled to a user interface 204, and to a signal processing command interface 208. The explanations provided herein for any other embodiment of the measurement application device apply mutatis mutandis to the measurement application device 200.

In addition to the elements of the measurement application device 100, the measurement application device 200 further comprises a code verification processor 215 that is coupled to the command memory 205 and the signal processing command interface 208. In embodiments, the code verification processor 215 may be coupled only to the command memory 205 or the signal processing command interface 208. The code verification processor 215 may inspect the received computer-readable extension commands 209 for compliance with a predetermined device rule set for the measurement application device. Such a device rule set may be stored in the code verification processor 215, or in the command memory 205.

The signal processor 203 may then reject the received computer-readable extension commands 209 if the code verification processor 215 determines that the received computer-readable extension commands 209 do not comply with the predetermined device rule set.

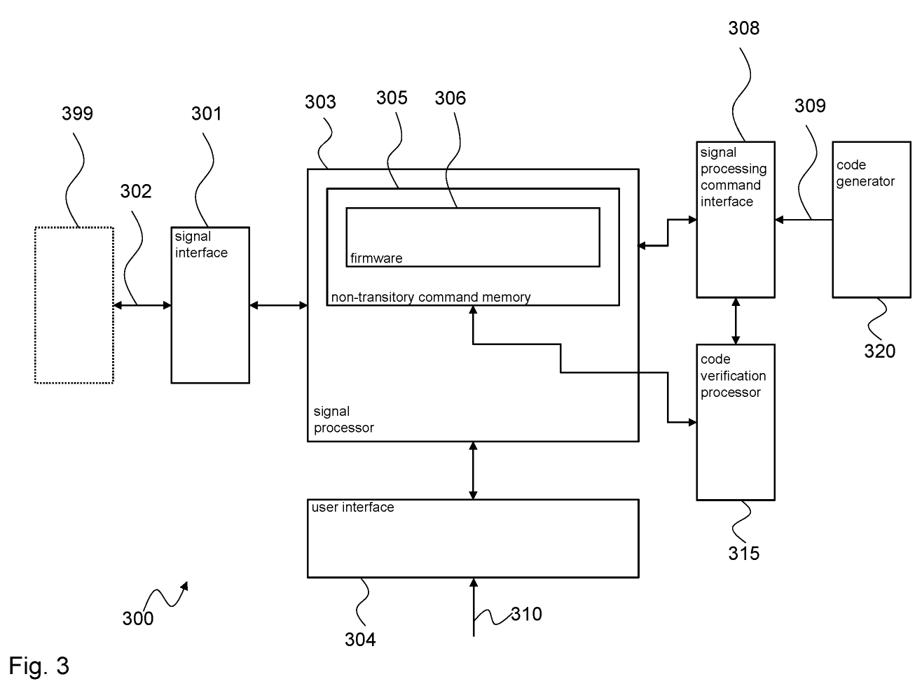

FIG. 3 shows a block diagram of a further measurement application device 300. The measurement application device 300 is based on the measurement application device 200. Therefore, the measurement application device 300 comprises a signal interface 301 that acquires and/or outputs a measurement application signal 302. The signal interface 301 is coupled to a signal processor 303. The signal processor 303 is coupled to a user interface 304, and to a signal processing command interface 308. The measurement application device 300 further comprises a code verification processor 315 that is coupled to the command memory 305 and the signal processing command interface 308.The explanations provided herein for any other embodiment of the measurement application device apply mutatis mutandis to the measurement application device 300.

The measurement application device 300 further comprises a code generator 320 that is coupled to the signal processing command interface 308.

The code generator 320 may generate the computer-readable extension commands 309. The code generator 320 may receive a respective user request directly or via the user interface 304 and provide the generated computer-readable extension commands 309 to the signal processing command interface 308.

The code generator 320 may, e.g., comprise a pre-trained artificial intelligence algorithm, like a large language model, that is pre-trained to generate computer-readable extension commands 309 for the measurement application device 300 based on the respective user request.

The code generator 320 may in embodiments provide computer-readable extension commands 309 that when executed by the signal processor cause the signal processor 303 to perform calculations based on the measurement application signal 302, and to control a display (not explicitly shown) of the measurement application device 300 to display the calculation results. Such computer-readable extension commands 309 enable the user to create new analysis methods that are not present in the firmware and display respective analysis results to the user.

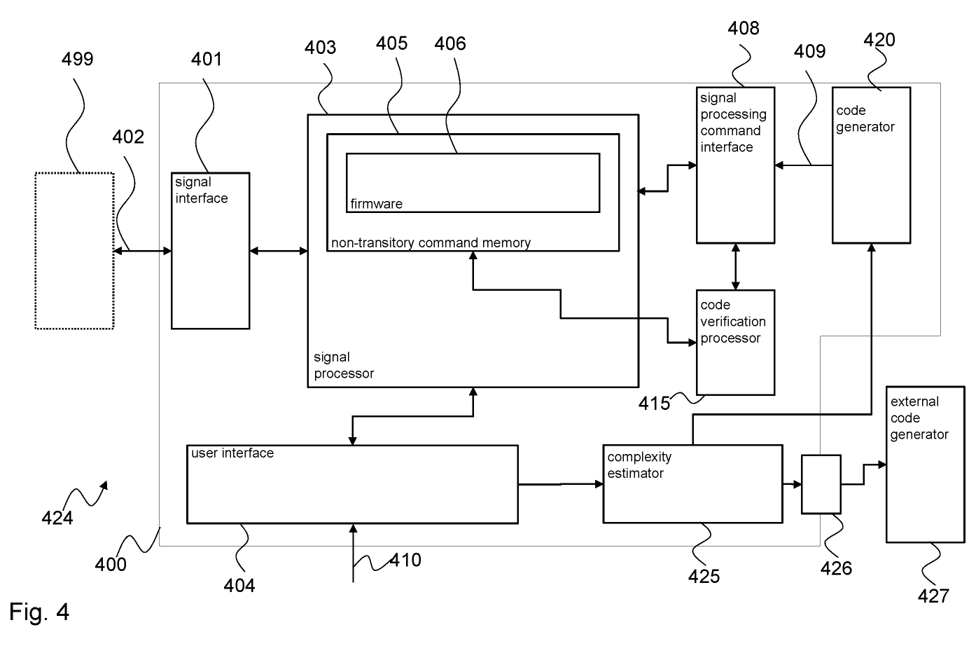

FIG. 4 shows a block diagram of a measurement application system 424. The measurement application system 424 comprises a measurement application device 400, and an external code generator 427.

The measurement application device 400 comprises a signal interface 401 that acquires and/or outputs a measurement application signal 402. The signal interface 401 is coupled to a signal processor 403. The signal processor 403 is coupled to a user interface 404, and to a signal processing command interface 408. The measurement application device 400 further comprises a code verification processor 415 that is coupled to the command memory 405 and the signal processing command interface 408.The explanations provided herein for any other embodiment of the measurement application device apply mutatis mutandis to the measurement application device 400.

The external code generator 427 may be provided with the same features as the code generator 420. The difference between the external code generator 427, and the code generator 420 may be that the external code generator 427 may comprise more processing capacity or processing power to process more complex user requests 410.

The measurement application device 400 further comprises a complexity estimator 425 that is coupled to the user interface 404, and to a communication interface 426.

The complexity estimator 425 determines the complexity of the respective user request 410, and provides the respective user request 410 to the internal code generator 420 of the measurement application device 400, if the determined complexity is below a predetermined threshold. The complexity estimator 425 may further provide the user request 410 to the external code generator 427 via the communication interface 426 if the determined complexity is above the predetermined threshold. In embodiments, the complexity estimator 425 may only provide the user request 410 to an external code generator 427 after querying for and receiving a respective user consent.

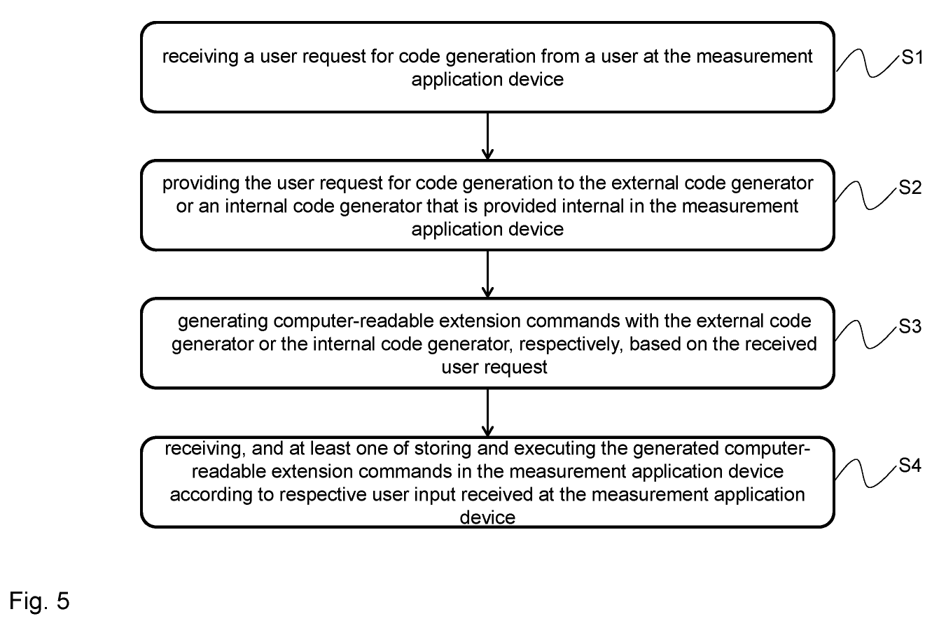

FIG. 5 shows a flow diagram of a method for operating a measurement application system that comprises a measurement application device and an external code generator that is external to the measurement application device.

The method comprises receiving S1 a user request for code generation from a user at the measurement application device, providing S2 the user request for code generation to the external code generator or an internal code generator that is provided internal in the measurement application device, generating S3 computer-readable extension commands with the external code generator or the internal code generator, respectively, based on the received user request, and receiving S4, and at least one of storing and executing the generated computer-readable extension commands in the measurement application device according to respective user input received at the measurement application device.

The internal code generator may be provided in the measurement application device, especially as a a pre-trained artificial intelligence code generator algorithm. The same applies for an external code generator.

The method may further comprise inspecting the received computer-readable extension commands for compliance with a predetermined device rule set for the measurement application device, wherein the received computer-readable extension commands are rejected if it is determined that the received computer-readable extension commands do not comply with the predetermined device rule set.

The method may also comprises determining the complexity of the respective user request, and providing the respective user request to the internal code generator if the determined complexity is below a predetermined threshold. Further, the method may comprise providing the user request to the external code generator via the communication interface if the determined complexity is above the predetermined threshold, and only providing the user request to the external code generator after receiving a respective user consent.

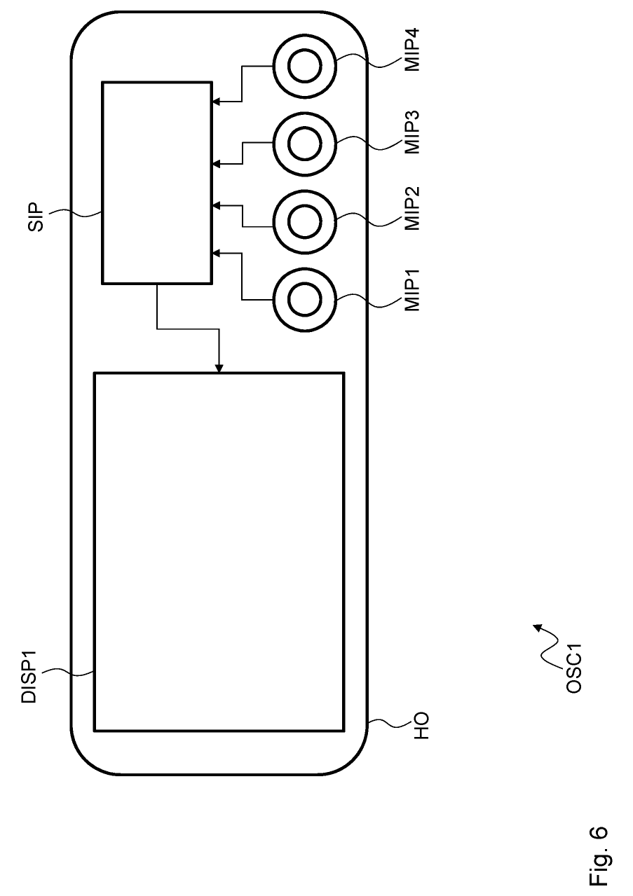

FIG. 6 shows a block diagram of an oscilloscope OSC1 that may be used with an embodiment of a measurement application device according to the present disclosure.

The oscilloscope OSC1 comprises a housing HO that accommodates four measurement inputs MIP1, MIP2, MIP3, MIP4 that are coupled to a signal processor SIP for processing any measured signals. The signal processor SIP is coupled to a display DISP1 for displaying the measured signals to a user.

Although not explicitly shown, it is understood, that the oscilloscope OSC1 may also comprise signal outputs. Such signal outputs may for example serve to output calibration signals. Such calibration signals allow calibrating the measurement setup prior to performing any measurement. The process of calibrating and correcting any measurement signals based on the calibration may also be called de-embedding and may comprise applying respective algorithms on the measured signals.

In the oscilloscope OSC1 the signal processor SIP or an additional processing element may perform the function of the signal processor, the code verification processor, the code generator, and the complexity estimator according to the present disclosure, or may implement the signal processor, the code verification processor, the code generator, and the complexity estimator. Of course, a communication interface may be provided in the oscilloscope OSC1 for communication with other measurement application devices.

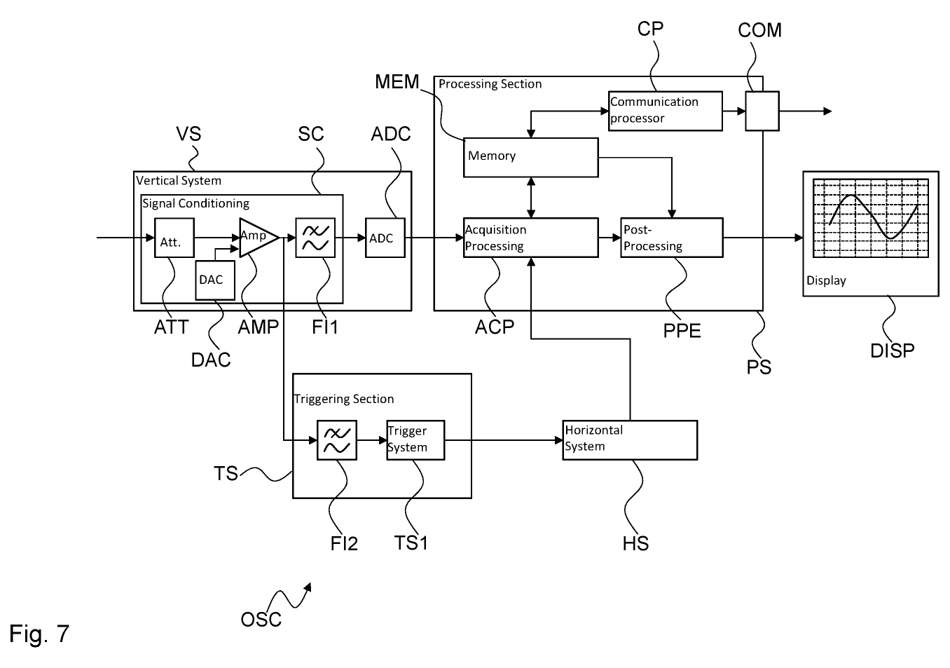

FIG. 7 shows a block diagram of an oscilloscope OSC that may be an implementation of a measurement application device according to the present disclosure. The oscilloscope OSC is implemented as a digital oscilloscope. However, the present disclosure may also be implemented with any other type of oscilloscope.

The oscilloscope OSC exemplarily comprises five general sections, the vertical system VS, the triggering section TS, the horizontal system HS, the processing section PS and the display DISP. It is understood, that the partitioning into five general sections is a logical partitioning and does not limit the placement and implementation of any of the elements of the oscilloscope OSC in any way.

The vertical system VS mainly serves for offsetting, attenuating and amplifying a signal to be acquired. The signal may for example be modified to fit in the available space on the display DISP or to comprise a vertical size as configured by a user.

To this end, the vertical system VS comprises a signal conditioning section SC with an attenuator ATT and a digital-to-analog-converter DAC that are coupled to an amplifier AMP. The amplifier AMP is coupled to a filter FI1, which in the shown example is provided as a low pass filter. The vertical system VS also comprises an analog-to-digital converter ADC that receives the output from the filter FI1 and converts the received analog signal into a digital signal.

The attenuator ATT and the amplifier AMP serve to scale the amplitude of the signal to be acquired to match the operation range of the analog-to-digital converter ADC. The digital-to-analog-converter DAC serves to modify the DC component of the input signal to be acquired to match the operation range of the analog-to-digital converter ADC. The filter FI1 serves to filter out unwanted high frequency components of the signal to be acquired.

The triggering section TS operates on the signal as provided by the amplifier AMP. The triggering section TS comprises a filter FI2, which in this embodiment is implemented as a low pass filter. The filter FI2 is coupled to a trigger system TS1.

The triggering section TS serves to capture predefined signal events and allows the horizontal system HS to e.g., display a stable view of a repeating waveform, or to simply display waveform sections that comprise the respective signal event. It is understood, that the predefined signal event may be configured by a user via a user input of the oscilloscope OSC.

Possible predefined signal events may for example include, but are not limited to, when the signal crosses a predefined trigger threshold in a predefined direction i.e., with a rising or falling slope. Such a trigger condition is also called an edge trigger. Another trigger condition is called “glitch triggering” and triggers, when a pulse occurs in the signal to be acquired that has a width that is greater than or less than a predefined amount of time.

In order to allow an exact matching of the trigger event and the waveform that is shown on the display DISP, a common time base may be provided for the analog-to-digital converter ADC and the trigger system TS1.

It is understood, that although not explicitly shown, the trigger system TS1 may comprise at least one of configurable voltage comparators for setting the trigger threshold voltage, fixed voltage sources for setting the required slope, respective logic gates like e.g., a XOR gate, and FlipFlops to generate the triggering signal.

The triggering section TS is exemplarily provided as an analog trigger section. It is understood, that the oscilloscope OSC may also be provided with a digital triggering section. Such a digital triggering section will not operate on the analog signal as provided by the amplifier AMP but will operate on the digital signal as provided by the analog-to-digital converter ADC.

A digital triggering section may comprise a processing element, like a processor, a DSP, a CPLD, an ASIC or an FPGA to implement digital algorithms that detect a valid trigger event.

The horizontal system HS is coupled to the output of the trigger system TS1 and mainly serves to position and scale the signal to be acquired horizontally on the display DISP.

The oscilloscope OSC further comprises a processing section PS that implements digital signal processing and data storage for the oscilloscope OSC. The processing section PS comprises an acquisition processing element ACP that is couple to the output of the analog-to-digital converter ADC and the output of the horizontal system HS as well as to a memory MEM and a post processing element PPE.

The acquisition processing element ACP manages the acquisition of digital data from the analog-to-digital converter ADC and the storage of the data in the memory MEM. The acquisition processing element ACP may for example comprise a processing element with a digital interface to the analog-to-digital converter ADC2 and a digital interface to the memory MEM. The processing element may for example comprise a microcontroller, a DSP, a CPLD, an ASIC or an FPGA with respective interfaces. In a microcontroller or DSP, the functionality of the acquisition processing element ACP may be implemented as computer readable instructions that are executed by a CPU. In a CPLD or FPGA the functionality of the acquisition processing element ACP may be configured in to the CPLD or FPGA opposed to software being executed by a processor.

The processing section PS further comprises a communication processor CP and a communication interface COM.

The communication processor CP may be a device that manages data transfer to and from the oscilloscope OSC. The communication interface COM for any adequate communication standard like for example, Ethernet, WIFI, Bluetooth, NFC, an infra-red communication standard, and a visible-light communication standard.

The communication processor CP is coupled to the memory MEM and may use the memory MEM to store and retrieve data.

Of course, the communication processor CP may also be coupled to any other element of the oscilloscope OSC to retrieve device data or to provide device data that is received from the management server.

The post processing element PPE may be controlled by the acquisition processing element ACP and may access the memory MEM to retrieve data that is to be displayed on the display DISP. The post processing element PPE may condition the data stored in the memory MEM such that the display DISP may show the data e.g., as waveform to a user. The post processing element PPE may also realize analysis functions like cursors, waveform measurements, histograms, or math functions.

The display DISP controls all aspects of signal representation to a user, although not explicitly shown, may comprise any component that is required to receive data to be displayed and control a display device to display the data as required.

It is understood, that even if it is not shown, the oscilloscope OSC may also comprise a user interface for a user to interact with the oscilloscope OSC. Such a user interface may comprise dedicated input elements like for example knobs and switches. At least in part the user interface may also be provided as a touch sensitive display device.

In the oscilloscope OSC, any one of the processing elements in the processing section PS or an additional processing element may perform the function of the the signal processor, the code verification processor, the code generator, and the complexity estimator according to the present disclosure.

It is understood, that all elements of the oscilloscope OSC that perform digital data processing may be provided as dedicated elements. As alternative, at least some of the above-described functions may be implemented in a single hardware element, like for example a microcontroller, DSP, CPLD or FPGA. Generally, the above-describe logical functions may be implemented in any adequate hardware element of the oscilloscope OSC and not necessarily need to be partitioned into the different sections explained above.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The abstract of the disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### LIST OF REFERENCE SIGNS

100, 200, 300, 400 measurement application device

101, 201, 301, 401 signal interface

102, 202, 302, 402 measurement application signal

103, 203, 303, 403 signal processor

104, 204, 304, 404 user interface

105, 205, 305, 405 non-transitory command memory

106, 206, 306, 406 firmware

108, 208, 308, 408 signal processing command interface

109, 209, 309, 409 computer-readable extension commands

110, 210, 310, 410 user input

215, 315, 415 code verification processor

320, 420 code generator

424 measurement application system

425 complexity estimator

426 communication interface

427 external code generator

199, 299, 399, 499 DUT

OSC1 oscilloscope

HO housing

MIP1, MIP2, MIP3, MIP4 measurement input

SIP signal processing

DISP1 display

OSC oscilloscope

VS vertical system

SC signal conditioning

ATT attenuator

DAC1 analog-to-digital converter

AMP amplifier

FI1 filter

DAC digital-to-analog converter

ADC analog-to-digital converter

TS triggering section

AMP2 amplifier

FI2 filter

TS1 trigger system

HS horizontal system

PS processing section

ACP acquisition processing element

MEM memory

PPE post processing element

DISP display

1. A measurement application device for at least one of acquiring from or generating for an electric device under test (DUT) at least one of electric, magnetic or electromagnetic signals, the measurement application device comprising:
a signal interface configured to at least one of acquire or output a measurement application signal;
a signal processor coupled to the signal interface, wherein the signal processor is configured at least one of to process a measurement application signal acquired by the signal interface or to process a measurement application signal to be output by the signal interface and provide the processed measurement application signal to the signal interface; and
a user interface coupled to the signal processor;
wherein the signal processor is coupled to or comprises a non-transitory command memory that comprises firmware with computer-readable commands that when executed by the signal processor at least cause the signal processor to perform the processing of the measurement application signal; and
wherein the measurement application device further comprises a signal processing command interface that is coupled to the command memory and that is configured to receive computer-readable extension commands, wherein the firmware further comprises computer-readable commands that when executed by the signal processor, cause the signal processor at least one of to store the received computer-readable extension commands in the command memory, or to execute the received computer-readable extension commands according to respective user input received via the user interface.

2. The measurement application device according to claim 1, further comprising:
a code verification processor that is coupled to either one or both of the command memory and the signal processing command interface, and that is configured to inspect the received computer-readable extension commands for compliance with a predetermined device rule set for the measurement application device;
wherein the signal processor is further configured to reject the received computer-readable extension commands if the code verification processor determines that the received computer-readable extension commands do not comply with the predetermined device rule set.

3. The measurement application device according to claim 1, further comprising a code generator that is coupled to the signal processing command interface and that is configured to generate the computer-readable extension commands based on a respective user request and provide the generated computer-readable extension commands to the signal processing command interface.

4. The measurement application device according to claim 3, wherein the code generator comprises a pre-trained artificial intelligence algorithm that is pre-trained to generate computer-readable extension commands for the measurement application device based on the respective user request.

5. The measurement application device according to claim 3, wherein the code generator is configured to provide computer-readable extension commands that when executed by the signal processor cause the signal processor to perform calculations based on the measurement application signal, and to control a display of the measurement application device to display the calculation results.

6. The measurement application device according to claim 3, further comprising a complexity estimator configured to determine a complexity of the respective user request, and provide the respective user request to the code generator if the determined complexity is below a predetermined threshold.

7. The measurement application device according to claim 6, further comprising a communication interface, wherein the complexity estimator is further configured to provide the respective user request to an external code generator that is external to the measurement application device via the communication interface if the determined complexity is above the predetermined threshold.

8. The measurement application device according to claim 7, wherein the complexity estimator is further configured to only provide the respective user request to the external code generator after receiving user consent.

9. A measurement application system comprising:
an external code generator configured to generate computer-readable extension commands based on a respective user request and to provide the generated computer-readable extension commands to a measurement application device; and
the measurement application device comprises:
a signal interface configured to at least one of acquire from or output for an electric DUT at least one of electric, magnetic or electromagnetic measurement application signal;
a signal processor coupled to the signal interface, wherein the signal processor is configured at least one of to process the measurement application signal acquired by the signal interface, or to process a measurement application signal to be output by the signal interface and provide the processed measurement application signal to the signal interface;
a user interface coupled to the signal processor; and
a communication interface coupled to the signal processor;
wherein the signal processor is coupled to or comprises a non-transitory command memory that comprises firmware with computer-readable commands that when executed by the signal processor at least cause the signal processor to perform the processing of the measurement application signal; and
wherein the measurement application device further comprises a signal processing command interface that is coupled to the command memory and that is configured to receive computer-readable extension commands, wherein the firmware further comprises computer-readable commands that when executed by the signal processor, cause the signal processor to at least one of store the received computer-readable extension commands in the command memory, or execute the received computer-readable extension commands according to respective user input received via the user interface;
wherein the signal processor is further configured to receive a user request for code generation from a user via the user interface, and to provide the user request for code generation to the external code generator via the communication interface or an internal code generator of the measurement application device, and to receive the computer-readable extension commands from the respective code generator via the signal processing command interface.

10. The measurement application system according to claim 9, wherein the measurement application device further comprises:
a code verification processor that is coupled to the command memory and that is configured to inspect the received computer-readable extension commands for compliance with a predetermined device rule set for the measurement application device;
wherein the signal processor is configured to reject the received computer-readable extension commands if the code verification processor determines that the received computer-readable extension commands do not comply with the predetermined device rule set.

11. The measurement application system according to claim 9, wherein the measurement application device further comprises the internal code generator that is coupled to the signal processing command interface and that is configured to generate the computer-readable extension commands based on the respective user request and provide the generated computer-readable extension commands to the signal processing command interface.

12. The measurement application system according to claim 11, wherein at least one of the internal code generator or the external code generator comprises a pre-trained artificial intelligence algorithm that is pre-trained to generate computer-readable extension commands for the measurement application device based on the respective user request.

13. The measurement application system according to claim 11, wherein at least one of the internal code generator or the external code generator is configured to provide computer-readable extension commands that when executed by the signal processor cause the signal processor to perform calculations based on the measurement application signal, and to control a display of the measurement application device to display the calculation results.

14. The measurement application system according to claim 11, wherein the measurement application device further comprises a complexity estimator configured to determine a complexity of the respective user request, and provide the respective user request to the internal code generator if the determined complexity is below a predetermined threshold.

15. The measurement application system according to claim 14, wherein the complexity estimator is further configured to provide the user request to the external code generator via the communication interface if the determined complexity is above the predetermined threshold.

16. The measurement application device according to claim 15, wherein the complexity estimator is further configured to only provide the user request to the external code generator after receiving a respective user consent.

17. A method for operating a measurement application system that comprises a measurement application device and an external code generator that is external to the measurement application device, the method comprising:
receiving a user request for code generation from a user at the measurement application device;
providing the user request for code generation to the external code generator or an internal code generator that is provided internal in the measurement application device;
generating computer-readable extension commands with the external code generator or the internal code generator, respectively, based on the received user request; and
receiving, and at least one of storing or executing, the generated computer-readable extension commands in the measurement application device according to respective user input received at the measurement application device.

18. The method according to claim 17, further comprising inspecting the received computer-readable extension commands for compliance with a predetermined device rule set for the measurement application device,
wherein the received computer-readable extension commands are rejected if it is determined that the received computer-readable extension commands do not comply with the predetermined device rule set.

19. The method according to claim 17, wherein the internal code generator is provided in the measurement application device as a pre-trained artificial intelligence code generator algorithm.

20. The method according to claim 17, further comprising at least one of:
determining a complexity of the respective user request, and providing the respective user request to the internal code generator if the determined complexity is below a predetermined threshold;
providing the user request to the external code generator via a communication interface if the determined complexity is above the predetermined threshold; or
providing the user request to the external code generator only after receiving user consent.
